(19) United States
(12) Patent Application Publication
(10) Pub. No.: US 2026/0136647 A1
(43) Pub. Date: May 14, 2026

(54) SEMICONDUCTOR DEVICE AND METHOD FOR FORMING THE SAME

(71) Applicant: TAIWAN SEMICONDUCTOR MANUFACTURING COMPANY, LTD., Hsinchu (TW)

(72) Inventors: Sheng-Po HUANG, New Taipei City (TW); Perng-Fei YUH, Walnut Creek, CA (US)

(73) Assignee: TAIWAN SEMICONDUCTOR MANUFACTURING COMPANY, LTD., Hsinchu (TW)

(21) Appl. No.: 18/948,270

(22) Filed: Nov. 14, 2024

(51) Int. Cl. H01L 27/06; H01L 21/8238; H01L 27/092; H01L 29/06; H01L 29/08; H01L 29/423; H01L 29/66; H01L 29/775; H01L 29/786

(52) U.S. Cl. CPC H10D 84/811; H10D 30/014; H10D 30/43; H10D 30/6735; H10D 30/6757; H10D 62/121; H10D 62/151; H10D 84/0186; H10D 84/0188; H10D 84/038; H10D 84/85

(57) ABSTRACT

A semiconductor device is provided. The semiconductor device comprises a first circuit and a capacitor circuit. The first circuit has an input terminal configured to receive an input signal. The capacitor circuit comprises a first transistor and a second transistor. The first transistor is coupled between a first supply voltage and the input terminal. Source/drain terminals of the first transistor are coupled to each other. The second transistor is stacked above the first transistor and coupled between a second supply voltage and the input terminal. Source/drain terminals of the second transistor are coupled to each other. The first and second transistors are decoupling capacitors of the first circuit.

### BACKGROUND

As the semiconductor industry further progresses into sub-10 nanometer (nm) technology process nodes in pursuit of higher device density, higher performance, and lower costs, challenges from both fabrication and design issues have led to stacked device structure configurations, such as complementary field effect transistors (C-FET) where a first transistor and a second transistor are stacked vertically, one over the other.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of a semiconductor device, in accordance with some embodiments of the present disclosure.

FIG. 2 is a schematic diagram of a capacitor circuit configured with respect to the capacitor circuit in FIG. 1, in accordance with some embodiments of the present disclosure.

FIG. 3 is a perspective view of a portion of the capacitor circuit of in FIG. 2, in accordance with some embodiments of the present disclosure.

FIG. 4A is a layout diagram corresponding to an upper portion of a capacitor circuit configured with respect to the capacitor circuits in FIGS. 1-3, in accordance with some embodiments of the present disclosure.

FIG. 4B is a layout diagram of a lower portion of the capacitor circuit in FIG. 4A, in accordance with some embodiments of the present disclosure.

FIG. 5 is a schematic diagram of a capacitor circuit configured with respect to the capacitor circuits in FIGS. 1-3, in accordance with some embodiments of the present disclosure.

FIG. 6 is a perspective view of a portion of the capacitor circuit in FIG. 5, in accordance with some embodiments of the present disclosure.

FIG. 7A is a layout diagram corresponding to an upper portion of a capacitor circuit configured with respect to the capacitor circuits in FIGS. 1-3, 4A-4B, 5-6 in accordance with some embodiments of the present disclosure.

FIGS. 7B-7C are layout diagrams of a lower portion of the capacitor circuit in FIG. 7A, in accordance with some embodiments of the present disclosure.

FIG. 8 is a schematic diagram of a capacitor circuit configured with respect to the capacitor circuits in FIGS. 1-3, 4A-4B, 5-6, 7A-7C in accordance with some embodiments of the present disclosure.

FIG. 9A is a schematic diagram of a capacitor circuit configured with respect to the capacitor circuits in FIGS. 1, 2, 3, 4A-4B, in accordance with some embodiments of the present disclosure.

FIG. 9B is a schematic diagram of a capacitor circuit configured with respect to the capacitor circuits in FIGS. 1, 2, 3, 4A-4B, in accordance with some embodiments of the present disclosure.

FIG. 10 is a flowchart diagram of a method for manufacturing the semiconductor device, capacitor circuits as shown in FIGS. 1-3, 4A-4B, 5-6, 7A-7C, 8, 9A-9B, in accordance with some embodiments of the present disclosure.

FIG. 11 is a block diagram of an electronic design automation (EDA) system for designing integrated circuit layout, in accordance with some embodiments of the present disclosure.

FIG. 12 is a block diagram of IC manufacturing system, and an IC manufacturing flow associated therewith, in accordance with some embodiments.

### DETAILED DESCRIPTION

The following disclosure provides many different embodiments, or examples, for implementing different features of the provided subject matter. Specific examples of components, materials, values, steps, arrangements or the like are described below to simplify the present disclosure. These are, of course, merely examples and are not intended to be limiting. Other components, materials, values, steps, arrangements or the like are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. The term mask, photolithographic mask, photomask and reticle are used to refer to the same item.

The terms applied throughout the following descriptions and claims generally have their ordinary meanings clearly established in the art or in the specific context where each term is used. Those of ordinary skill in the art will appreciate that a component or process may be referred to by different names. Numerous different embodiments detailed in this specification are illustrative only, and in no way limits the scope and spirit of the disclosure or of any exemplified term.

It is worth noting that the terms such as “first” and “second” used herein to describe various elements or processes aim to distinguish one element or process from another. However, the elements, processes and the sequences thereof should not be limited by these terms. For example, a first element could be termed as a second element, and a second element could be similarly termed as a first element without departing from the scope of the present disclosure.

In the following discussion and in the claims, the terms “comprising,” “including,” “containing,” “having,” “involving,” and the like are to be understood to be open-ended, that is, to be construed as including but not limited to. As used herein, instead of being mutually exclusive, the term “and/or” includes any of the associated listed items and all combinations of one or more of the associated listed items.

Circuits like a power delivery network for high-bandwidth memory and high-speed computation requires large decoupling capacitance to reduce power and ground bounce. With the increasing density and shrinking size of integrated circuits designed recently, the performance and efficiency required for the decoupling capacitors are increasing accordingly. For example, higher capacitance per area rate is required.

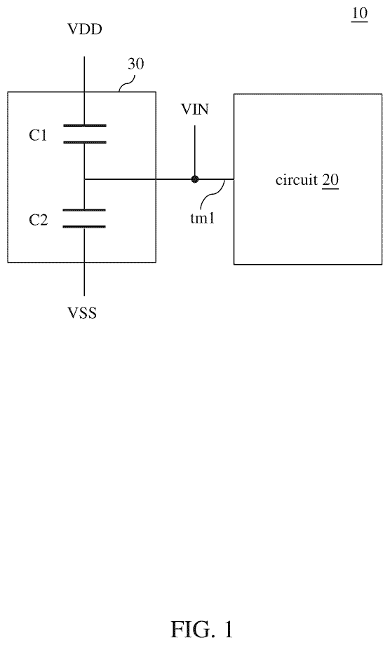

Reference is now made to FIG. 1. FIG. 1 is a schematic diagram of a semiconductor device 10, in accordance with some embodiments of the present disclosure. For illustration, the semiconductor device 10 includes a circuit 20 and a capacitor circuit 30. An input terminal tm1 of the circuit 20 is coupled to an input signal (voltage) VIN and the capacitor circuit 30. The capacitor circuit 30 is configured to provide compensation and/or decoupling capacitors to the circuit 20. The circuit 20 may include a charge pump, a digital low drop-out regulator (LDO), or any circuit that requires compensation and/or decoupling capacitors at the input terminal.

The capacitor circuit 30 is coupled between a supply voltage VDD and a supply voltage VSS. In some embodiments, the supply voltage VSS is a ground voltage. In some embodiments, the supply voltage VSS is configured as 0 volts. In some embodiments, the supply voltage VDD is higher than the supply voltage VSS. In some embodiments, the voltage level of the input signal VIN is configured between the supply voltage VDD and the supply voltage VSS. For example, the input signal VIN may be lower or equal to the supply voltage VDD and higher or equal to the supply voltage VSS. Specifically, the circuit 20 may be an analog circuit receiving the input signal VIN which is an analog signal having a voltage level range from the supply voltage VDD to the supply voltage VSS.

As shown in FIG. 1, the capacitor circuit 30 includes a capacitor C1 and a capacitor C2. The capacitors C1 and C2 are configured as compensation and/or decoupling capacitors to the circuit 20. For example, in some embodiments, the capacitors C1 and C2 are configured to suppress high-frequency noise in the input signal VIN.

The capacitor C1 has first and second terminals that are coupled to the supply voltage VDD and the input signal VIN respectively. The capacitor C2 has first and second terminals that are coupled to the input signal VIN and the supply voltage VSS respectively. The second terminal of the capacitor C1 is coupled to the first terminal of the capacitor C2. Specifically, the second terminal of the capacitor C1, the first terminal of the capacitor C2, the input signal VIN and the input terminal tm1 are coupled to each other.

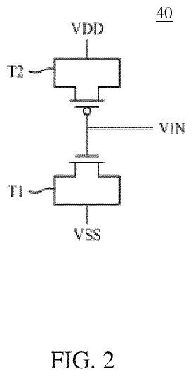

Reference is now made to FIG. 2. FIG. 2 is a schematic diagram of a capacitor circuit 40 configured with respect to the capacitor circuit 30 in FIG. 1, in accordance with some embodiments of the present disclosure. With respect to the embodiments of FIG. 1, like elements in FIG. 2 are designated with the same annotations and/or reference numbers for ease of understanding. The specific operations of similar elements, which are already discussed in detail in previous paragraphs, are omitted for the sake of brevity.

Compared with the capacitor circuit 30, the capacitor circuit 40 includes a transistor T1 and a transistor T2 that correspond to the capacitors C2 and C1 respectively. Specifically, in the capacitor circuit 40, the capacitors C1 and C2 are implemented by the transistors T2 and T1 respectively.

The source/drain terminals of the transistor T2 correspond to the first terminal of the capacitor C1. The gate terminal of the transistor T2 corresponds to the second terminal of the capacitor C1. Similarly, the gate terminal of the transistor T1 corresponds to the first terminal of the capacitor C2. The source/drain terminals of the transistor T1 correspond to the second terminal of the capacitor C2.

As shown in FIG. 2, the source/drain terminals of the transistor T2 are coupled to the supply voltage VDD. The gate terminal of the transistor T2 is coupled to the input signal VIN (i.e., coupled to the input terminal tm1) and the gate terminal of the transistor T1. The source/drain terminals of the transistor T1 are coupled to the supply voltage VSS.

In some embodiments, the transistor T1 of the capacitor circuit 40 is a P-type metal-oxide-semiconductor field-effect transistor (PMOS). The transistor T2 of the capacitor circuit 40 is an N-type metal-oxide-semiconductor field-effect transistor (NMOS).

In some embodiments, the transistors T1 and T2 of the capacitor circuit are implemented by a complementary field-effect transistor (CFET) structure. Compared to some approaches, the capacitor circuit implemented by the CFET has better area performance (i.e., consuming less layout area).

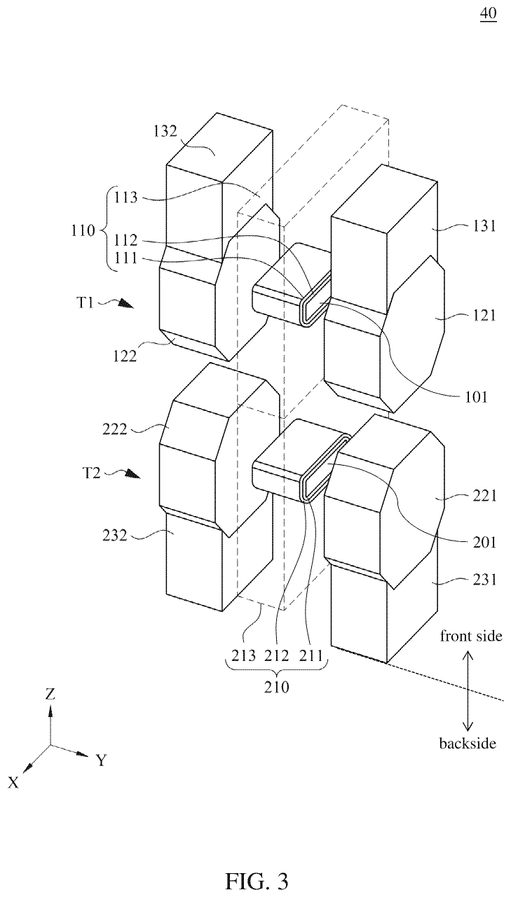

Reference is now made to FIG. 3. FIG. 3 is a perspective view of a portion of the capacitor circuit 40 of in FIG. 2, in accordance with some embodiments of the present disclosure. With respect to the embodiments of FIGS. 1-2, like elements in FIG. 3 are designated with the same annotations and/or reference numbers for ease of understanding.

As shown in FIG. 3, the capacitor circuit 40 includes transistors T1 and T2 in the CFET structure. In some embodiments, the transistor T2 are disposed over a substrate (not shown), and the transistor T1 are disposed above the transistor T2 along a direction Z.

In some embodiments, the transistors T1 and T2 are field effect transistors (FETs) and both include gate-all-around (GAA) configuration, and thus the transistors T1 and T2 can also be referred to as GAA FETs.

For illustration, the transistor T1 includes a semiconductor channel layer 101, a metal gate structure 110 wrapping around the semiconductor channel layer 101, and source/drain epitaxy structures 121 and 122. The channel layer 101 extends along a direction Y and the source/drain epitaxy structures 121 and 122 are in contact with opposite ends of the semiconductor channel layer 101. Similarly, the transistor T2 includes a semiconductor channel layer 201, a metal gate structure 210 wrapping around the semiconductor channel layer 201, and source/drain epitaxy structures 221 and 222. The channel layer 201 extends along the direction Y and the source/drain epitaxy structures 221 and 222 are in contact with opposite ends of the semiconductor channel layer 201.

The metal gate structure 110 includes an interfacial layer 112, a gate dielectric layer 111, and a gate electrode 113. Similarly, the metal gate structure 210 includes an interfacial layer 212, a gate dielectric layer 211, and a gate electrode 213. The metal gate structure is disposed above the metal gate structure 210 along the direction Z and is in contact with the metal gate structure 220.

In some embodiments, the interfacial layers 112 and 212 may be made of oxide, such as aluminum oxide (Al2O3), silicon oxide (SiO2), or the like. In some embodiments, the gate dielectric layers 174 and 274 may include high-k dielectric. Examples of high-k dielectric material include HfO2, HfSiO, HfSiON, HfTaO, HfTiO, HfZrO, zirconium oxide, aluminum oxide, titanium oxide, hafnium dioxide-alumina (HfO2—Al2O3) alloy, other suitable high-k dielectric materials, and/or combinations thereof.

The gate electrodes 113 and 213 may include work function metal layer(s) and a filling metal. The work function metal layer may be an n-type or p-type work function layer. Exemplary p-type work function metals include TiN, TaN, Ru, Mo, Al, WN, ZrSi2, MoSi2, TR1 asi2, NiSi2, WN, other suitable p-type work function materials, or combinations thereof. Exemplary n-type work function metals include Ti, Ag, TaAl, TaAlC, TiAlN, TaC, TaCN, TR1 asiN, Mn, Zr, other suitable n-type work function materials, or combinations thereof. The work function layer may include a plurality of layers. The filling metal may include tungsten (W), aluminum (Al), copper (Cu), or another suitable conductive material(s).

The metal gate structure 110 corresponds to the gate terminal of the transistor T1 and the metal gate structure 210 corresponds to the gate terminal of the transistor T2.

In some embodiments, the metal gate structures 110 and 210 are coupled to a metal line transmitting the input signal VIN.

The source/drain epitaxy structures 121, 122, 221 and 222 may be formed by suitable deposition process, such as a selective epitaxial growth (SEG) process. In some embodiments, the SEG process may selectively grow a semiconductor material on exposed semiconductor surfaces, such as the exposed surfaces of the substrate and the exposed surfaces of the semiconductor channel layers 101 and 202. In some embodiments, an implantation process may be performed to the source/drain epitaxy structures 121, 122, 221 and 222. For example, the implantation process may include p-type dopants, such as boron (B), gallium (Ga), indium (In), aluminum (Al), or the like, such that the source/drain epitaxy structures 121 and 122 are p-type epitaxy structures. The implantation process may include n-type dopants, such as phosphorus (P), arsenic (As), or antimony (Sb), or the like, such that the source/drain epitaxy structures 221 and 222 are n-type epitaxy structures.

The circuit 60 further includes source/drain contacts 131, 132, 231 and 232. The source/drain contacts 131 and 132 are disposed over the source/drain epitaxy structures 121 and 122 respectively. In some embodiments, the source/drain contacts 131 and 132 are in contact with top surfaces of the source/drain epitaxy structures 121 and 122 respectively.

The source/drain contacts 231 and 232 are disposed below the source/drain epitaxy structures 221 and 222 respectively. In some embodiments, the source/drain contacts 231 and 232 are in contact with bottom surfaces of the source/drain epitaxy structures 221 and 222 respectively.

The source/drain contacts 131 and 132 correspond to the source/drain terminals of the transistor T1 and source/drain contacts 231 and 232 correspond to the source/drain terminals of the transistor T2.

In some embodiments, the source/drain contacts 131 and 132 are coupled to a metal line transmitting the supply voltage VSS. The source/drain contacts 231 and 232 are coupled to a metal line transmitting the supply voltage VDD.

In some embodiments, the source/drain contacts 131, 132, 231 and 232 may include tungsten (W), copper (Cu), aluminum (Al), ruthenium (Ru), cobalt (Co), molybdenum (Mo), nickel (Ni), or other suitable conductive material.

In some embodiments, the semiconductor device 10 is referred to as an integrated circuit structure including active semiconductor devices (i.e., with active regions, gate structures, metal-on-device MD on the active regions, etc.) and front side metal routing on its front side and some metal routing on its backside. In some embodiments, the active semiconductor device on the front side of the semiconductor device 10 is formed on a substrate in a front side process. After the front side process is complete, the semiconductor device 10 is flipped upside down, such that a backside surface of the substrate faces upwards. The substrate is further thinned down. In some embodiments, thinning is accomplished by a chemical mechanical planarization (CMP) process, a grinding process, or the like. Accordingly, backside process is performed to form structures on the backside of the semiconductor device 10.

As shown in FIG. 3, the portion of the capacitor circuit 40 under the bottom of the source/drain contacts 231 and 232 corresponds to the backside. On the contrary, the portion of the capacitor circuit 40 above the bottom of the source/drain contacts 231 and 232 corresponds to the front side.

In some embodiments, the capacitor circuit 40 further includes metal routing in the backside and metal routing above the source/drain contacts 131, 132 and the metal gate structure 110 in the front side.

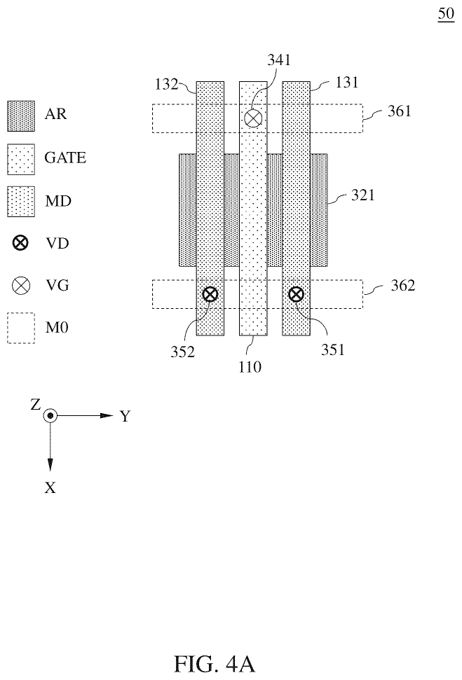

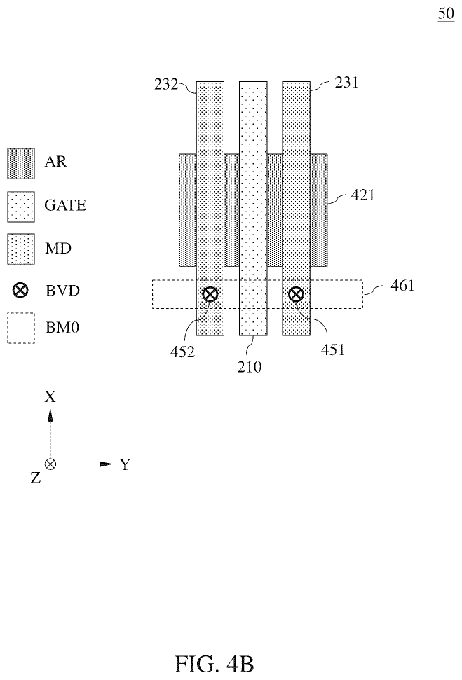

Reference is now made to FIGS. 4A-4B. FIG. 4A is a layout diagram corresponding to an upper portion of a capacitor circuit 50 configured with respect to the capacitor circuits 30, 40 in FIGS. 1-3, in accordance with some embodiments of the present disclosure. FIG. 4B is a layout diagram of a lower portion of the capacitor circuit 50, in accordance with some embodiments of the present disclosure. With respect to the embodiments of FIGS. 1-3, like elements in FIGS. 4A-4B are designated with the same annotations and/or reference numbers for ease of understanding.

As shown in FIG. 4A, compared with the capacitor circuit 40, the capacitor circuit 50 further includes a gate via 341, a via 351, a via 352, a metal line 361 and a metal line 362. The semiconductor channel layer 101, the source/drain epitaxy structures 121 and 122 are together referred to as an active region (AR) 321 extending along the direction Y.

The source/drain contacts 131 and 132 are in a first metal to device (MD) layer and extend along a direction X to contact the vias 351 and 352 respectively. The vias 351 and 352 extend along the direction Z in a via over diffusion (VD) layer above the first MD layer to contact the metal line 362. The metal line 362 extends along the direction Y in a metal zero (M0) layer above the VD layer.

The metal gate structure 110 extends along the direction X to contact the gate via 341. The gate via 341 extends along the direction Z in a via over gate (VG) layer above the metal gate structure 110 to contact the metal line 361 extending along the direction Y in the M0 layer.

In some embodiments, the metal line 361 is configured to transmit the input signal VIN. In some embodiments, the metal line 361 is coupled to the input terminal tm1. The metal line 362 is configured to transmit the supply voltage VSS.

As shown in FIG. 4B, compared with the capacitor circuit 40, the capacitor circuit 50 further includes a via 451, a via 452 and a metal line 461. The semiconductor channel layer 201, the source/drain epitaxy structures 221 and 222 are together referred to as an active region (AR) 421 extending along the direction Y.

The source/drain contacts 231 and 232 are in a second metal to device (MD) layer and extend along a direction X to contact the vias 451 and 452 respectively. The vias 451 and 452 extend along the direction Z in a backside via over diffusion (VD) layer below the second MD layer to contact the metal line 461. The metal line 461 extends along the direction Y in a backside metal zero (M0) layer below the backside VD layer. The backside VD layer and the backside M0 layer are in the backside of the semiconductor device 10.

In some embodiments, the metal line 461 is configured to transmit the supply voltage VDD.

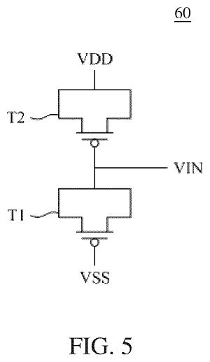

Reference is now made to FIG. 5. FIG. 5 is a schematic diagram of a capacitor circuit 60 configured with respect to the capacitor circuits 30, 40 in FIGS. 1-3, in accordance with some embodiments of the present disclosure. With respect to the embodiments of FIGS. 1-3, like elements in FIG. 5 are designated with the same annotations and/or reference numbers for ease of understanding.

Compared with the transistor T1 of the capacitor circuit 40, the source/drain terminals of the transistor T1 of the capacitor circuit 60 are coupled to the gate terminal of the transistor T2 and the input signal VIN. The gate terminal of the transistor T1 of the capacitor circuit 60 is coupled to the supply voltage VSS. In some embodiments, the transistor T1 of the capacitor circuit 60 is a PMOS.

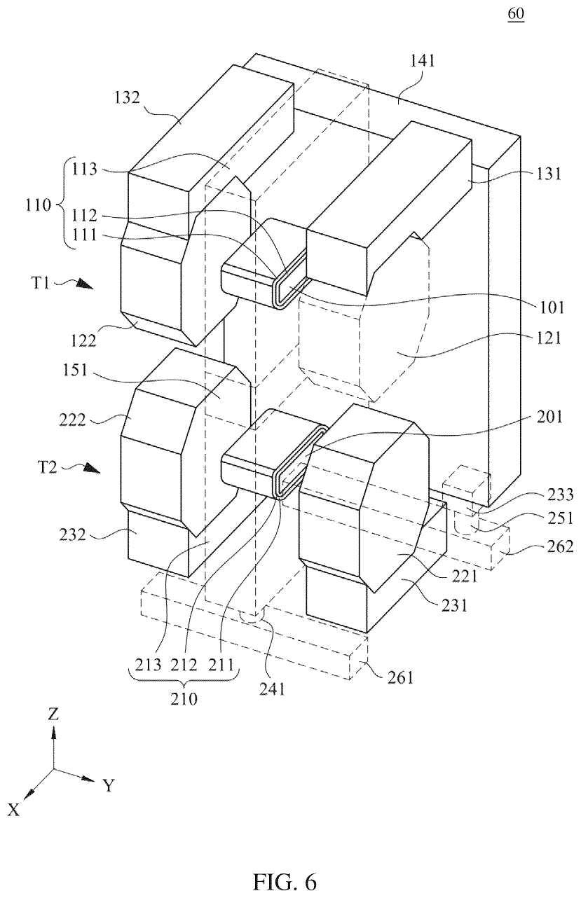

Reference is now made to FIG. 6. FIG. 6 is a perspective view of a portion of the capacitor circuit 60 in FIG. 5, in accordance with some embodiments of the present disclosure. With respect to the embodiments of FIGS. 1-3, like elements in FIG. 6 are designated with the same annotations and/or reference numbers for ease of understanding.

Compared with the capacitor circuit 40, the capacitor circuit 60 further includes an interconnect structure 141, a gate isolation 151, a source/drain contact 233, a gate via 241, a via 251, a metal line 261 and a metal line 262.

The interconnect structure 141 is also referred to as MD local interconnect (MDLI). The interconnect structure 141 is configured to couple the source/drain contacts 131-132 to the source/drain contact 233. The via 251 couples the source/drain contact 233 to the metal line 262.

The gate via 241 couples the metal gate structure 210 to the metal line 261. In some embodiments, the metal line 261 is coupled to the metal line 262 (not shown).

The gate isolation 151 is between the metal gate structures 110 and 210. The gate isolation 151 is configured to electrically separated the metal gate structure 110 from the metal gate structure 210.

The implantation process includes p-type dopants, such as boron (B), gallium (Ga), indium (In), aluminum (Al), or the like, such that the first source/drain epitaxy structures 121 and 122 are p-type epitaxy structures.

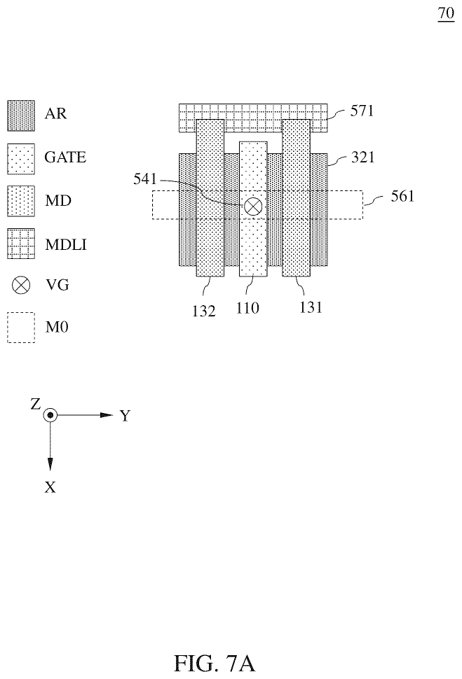

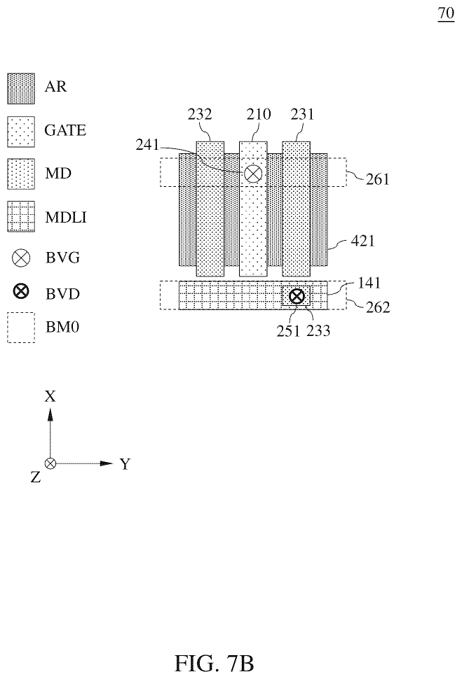

Reference is now made to FIGS. 7A-7C. FIG. 7A is a layout diagram corresponding to an upper portion of a capacitor circuit 70 configured with respect to the capacitor circuits 30, 40, 50, 60 in FIGS. 1-3, 4A-4B, 5-6 in accordance with some embodiments of the present disclosure. FIGS. 7B-7C are layout diagrams of a lower portion of the capacitor circuit 70, in accordance with some embodiments of the present disclosure. With respect to the embodiments of FIGS. 1-3, 4A-4B, 5-6, like elements in FIGS. 7B-7C are designated with the same annotations and/or reference numbers for ease of understanding.

As shown in FIG. 7A, compared with the capacitor circuit 60, the capacitor circuit 70 further includes a gate via 541 and a metal line 561.

The gate via 541 extends along the direction Z in the VG layer above the metal gate structure 110 to contact the metal line 561 extending along the direction Y in the M0 layer.

In some embodiments, the metal line 561 is configured to transmit the supply voltage VSS.

As shown in FIG. 7B, the gate via 241 extends along the direction Z in a backside gate via (BVG) layer below the metal gate structure 210 to contact the metal line 261 extending along the direction Y in the BM0 layer.

The source/drain contact 233 is disposed in the second MD layer to couple the interconnect structure 141 to the via 251.

The via 251 extends along the direction Z in the BVD layer to contact the metal line 262 extending along the direction Y in the BM0 layer.

As shown in FIG. 7C, compared with the capacitor circuit 60, the capacitor circuit 70 further includes a via 651, a via 652 and a metal line 661.

The vias 651-652 extend along the direction Z in a backside via zero (BV0) layer below the BM0 layer to couples the metal lines 261-262 to the metal line 661 extending along the direction X in a backside metal one (BM1) layer below the BV0 layer. The BV0 and BM1 layers are in the backside of the semiconductor device 10.

In some embodiments, the metal line 661 is configured to transmit the input signal VIN. In some embodiments, the metal line 661 is coupled to the input terminal tm1.

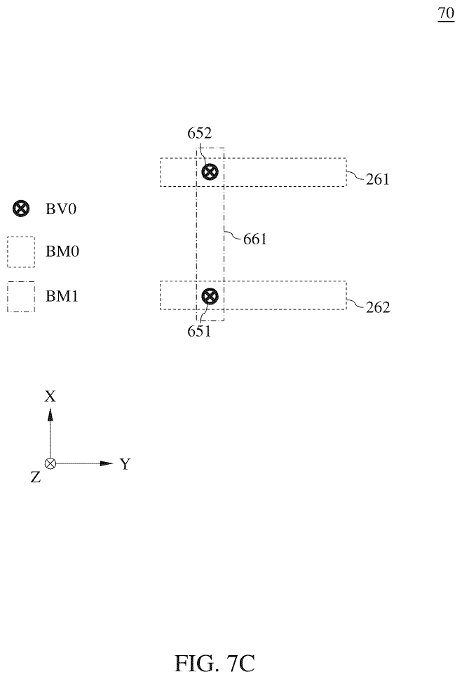

Reference is now made to FIG. 8. FIG. 8 is a schematic diagram of a capacitor circuit 80 configured with respect to the capacitor circuits 30, 40, 50, 60, 70 in FIGS. 1-3, 4A-4B, 5-6, 7A-7C in accordance with some embodiments of the present disclosure. With respect to the embodiments of FIGS. 1-3, 4A-4B, 5-6, 7A-7C, like elements in FIG. 8 are designated with the same annotations and/or reference numbers for ease of understanding.

Compared with the transistors T1-T2 of the capacitor circuit 60, the gate terminal of the transistor T1 of the capacitor circuit 80 is coupled to the supply voltage VDD. The source/drain terminals of the transistor T2 are coupled to the supply voltage VSS. The transistors T1 and T2 are NMOSs.

In some embodiments, the capacitor circuit 80 includes semiconductor channel layers 101 and 201, metal gate structures 110 and 220, source/drain epitaxy structures 121-122 and 221-222, and source/drain contacts 131-132 and 231-232, the interconnect structure 141, the gate isolation 151, the source/drain contact 233, the gate via 241, the via 251, the metal line 261 and the metal line 262 with configurations similar to the capacitor circuit 60 shown in FIG. 6.

The source/drain epitaxy structures 121, 122, 221 and 222 of the capacitor circuit 80 are n-type epitaxy structures.

The metal gate structure 110 of the capacitor circuit 80 is coupled to the supply voltage VDD. The source/drain contacts 231-232 of the capacitor circuit 80 are coupled to the supply voltage VSS.

In some embodiments, the capacitor circuit 80 further includes a gate via 541, a metal line 561, a via 651, a via 652 and a metal line 661 with configurations similar to the capacitor circuit 70 shown in FIGS. 7A-7C. The metal line 561 of the capacitor 80 is configured to transmit the supply voltage VDD.

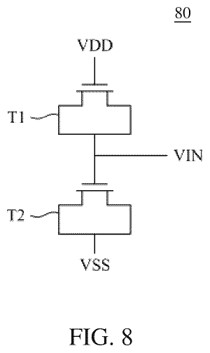

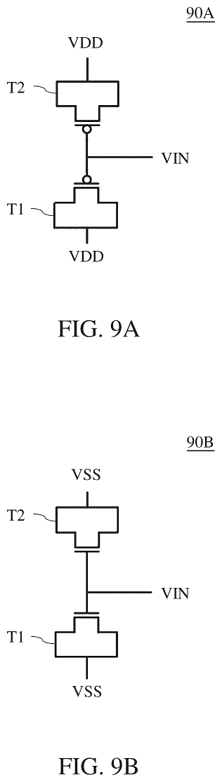

Reference is now made to FIG. 9A. FIG. 9A is a schematic diagram of a capacitor circuit 90A configured with respect to the capacitor circuits 30, 40, 50 in FIGS. 1, 2, 3, 4A-4B, in accordance with some embodiments of the present disclosure. With respect to the embodiments of FIGS. 1, 2, 3, 4A-4B, like elements in FIG. 9A are designated with the same annotations and/or reference numbers for ease of understanding.

Compared with the transistors T1 of the capacitor circuits 40 and 50, the transistor T1 of the capacitor circuit 90A is a PMOS. The source/drain terminals of the transistor T1 of the capacitor circuit 60 is coupled to the supply voltage VDD.

Compared with the capacitor circuits 40 and 50, the capacitance of the capacitor circuit 90A is greater (e.g., twice larger) and the range of the input signal VIN of the capacitor circuit 90A is smaller (e.g., from the supply voltage VSS to half of the supply voltage VDD).

In some embodiments, the capacitor circuit 90A includes semiconductor channel layers 101 and 201, metal gate structures 110 and 220, source/drain epitaxy structures 121-122 and 221-222, and source/drain contacts 131-132 and 231-232 with configurations similar to the capacitor circuit 40 shown in FIG. 3.

In some embodiments, the source/drain contacts 131-132 of the capacitor circuit 90A are coupled to a metal line transmitting the supply voltage VDD in the M0 layer. The source/drain contacts 231-232 of the capacitor circuit 60 are coupled to a metal line transmitting the supply voltage VDD in the backside M0 layer.

In some embodiments, the source/drain contacts 131-132 and 231-232 of the capacitor circuit 60 are coupled to metal lines transmitting the supply voltage VDD in the M0 layer. In some embodiments, the source/drain contacts 131-132 and 231-232 of the capacitor circuit 60 are coupled to metal lines transmitting the supply voltage VDD in the backside M0 layer.

In some embodiments, the capacitor circuit 90A further includes a gate via 341, a via 351, a via 352, a metal line 361, a metal line 362, a via 451, a via 452 and a metal line 461 with configurations similar to the capacitor circuit 50 shown in FIGS. 4A-4B. The difference between the capacitor circuit 90A and capacitor circuit 50 is that the metal line 362 is configured to transmit the supply voltage VDD and the active region 321 is P-type.

Reference is now made to FIG. 9B. FIG. 9B is a schematic diagram of a capacitor circuit 90B configured with respect to the capacitor circuits 30, 40, 50 in FIGS. 1, 2, 3, 4A-4B, in accordance with some embodiments of the present disclosure. With respect to the embodiments of FIGS. 1, 2, 3, 4A-4B, like elements in FIG. 9B are designated with the same annotations and/or reference numbers for ease of understanding.

Compared with the transistors T2 of the capacitor circuits 40 and 50, the transistor T2 of the capacitor circuit 90B is an NMOS. The source/drain terminals of the transistor T2 of the capacitor circuit 60 is coupled to the supply voltage VSS.

Compared with the capacitor circuits 40 and 50, the capacitance of the capacitor circuit 90B is greater (e.g., twice larger) and the range of the input signal VIN of the capacitor circuit 90B is smaller (e.g., from the supply voltage VDD to half of the supply voltage VDD).

In some embodiments, the capacitor circuit 90B includes semiconductor channel layers 101 and 201, metal gate structures 110 and 220, source/drain epitaxy structures 121-122 and 221-222, and source/drain contacts 131-132 and 231-232 with configurations similar to the capacitor circuit 40 shown in FIG. 3.

In some embodiments, the source/drain contacts 131-132 of the capacitor circuit 90A are coupled to a metal line transmitting the supply voltage VSS in the M0 layer. The source/drain contacts 231-232 of the capacitor circuit 60 are coupled to a metal line transmitting the supply voltage VSS in the backside M0 layer.

In some embodiments, the source/drain contacts 131-132 and 231-232 of the capacitor circuit 60 are coupled to metal lines transmitting the supply voltage VSS in the M0 layer. In some embodiments, the source/drain contacts 131-132 and 231-232 of the capacitor circuit 60 are coupled to metal lines transmitting the supply voltage VSS in the backside M0 layer.

In some embodiments, the capacitor circuit 90B further includes a gate via 341, a via 351, a via 352, a metal line 361, a metal line 362, a via 451, a via 452 and a metal line 461 with configurations similar to the capacitor circuit 50 shown in FIGS. 4A-4B. The difference between the capacitor circuit 90B and capacitor circuit 50 is that the metal line 461 is configured to transmit the supply voltage VSS and the active region 421 is N-type.

The configurations of FIGS. 1-3, 4A-4B, 5-6, 7A-7C, 8, 9A-9B are given for illustrative purposes. Various implements are within the contemplated scope of the present disclosure. For example, in some embodiments, the number of the semiconductor channel layers 101 and 201 can be more than one (e.g., two semiconductor channel layers 101 and two semiconductor channel layers 201 stacked vertically). In some embodiment, the configurations of the capacitor circuits 40, 50, 60, 70, 80, 90A-90B are flipped vertically, the portion thereof under the bottom surface (the top surface shown in FIG. 3) of source/drain contacts 131-132 corresponds to the backside, and the portion thereof above the bottom surface (the top surface shown in FIG. 3) of source/drain contacts 131-132 corresponds to the front side.

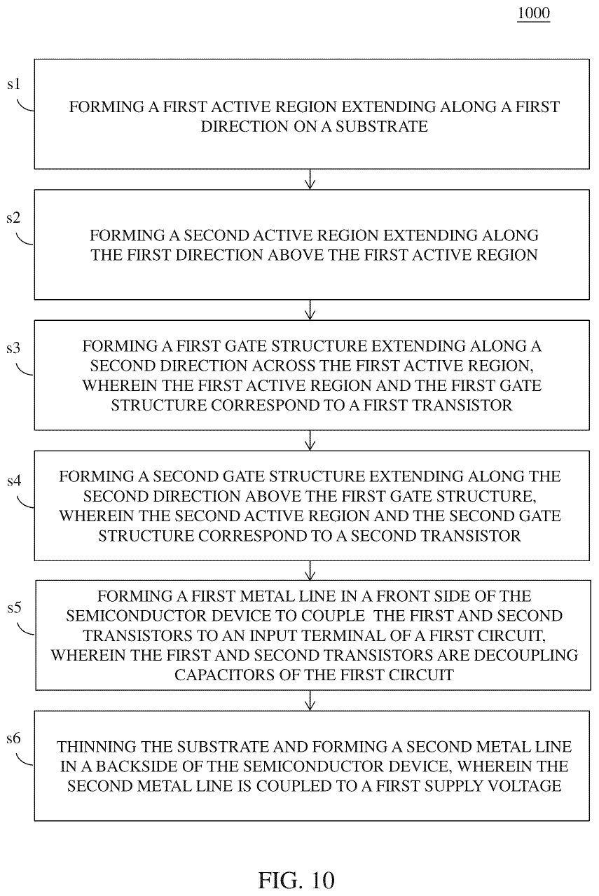

Reference is now made to FIG. 10. FIG. 10 is a flowchart diagram of a method 1000 for manufacturing the semiconductor device 10, capacitor circuits 30, 40, 50, 60, 70, 80, 90A-90B as shown in FIGS. 1-3, 4A-4B, 5-6, 7A-7C, 8, 9A-9B, in accordance with some embodiments of the present disclosure. It is understood that additional steps can be provided before, during, and after the steps shown by FIG. 10, and some of the steps described below can be replaced or eliminated, for additional embodiments of the method. The order of the steps may be interchangeable. Some of the steps are performed concurrently. Throughout the various views and illustrative embodiments, like annotations and reference numbers are used to designate like elements. The method 1000 includes steps s1-s6 that are described below with reference to the semiconductor device 10, capacitor circuits 30, 40, 50, 60, 70, 80, 90A-90B corresponding to FIGS. 1-3, 4A-4B, 5-6, 7A-7C, 8, 9A-9B.

In step s1, the active region 421 extending along the direction Y is formed on the substrate.

In step s2, the active region 321 extending along the direction Y is formed above the active region 421.

In step s3, the metal gate structure 210 extending along the direction X across the active region 421 is formed. The metal gate structure 210 and the active region 421 correspond to the transistor T2.

In step s4, the metal gate structure 110 extending along the direction X above the metal gate structure 210. The metal gate structure 110 and the active region 321 correspond to the transistor T1.

In step s5, a first metal line (e.g., metal line 361) in the front side of the semiconductor device 10 is formed to couple the transistors T1-T2 to the input terminal tm1 of the circuit 20. The transistors T1-T2 are decoupling capacitors of the circuit 20.

In step s6, the substrate is thinned and a second metal line (e.g., metal line 461) is formed in the backside of the semiconductor. The second metal line is coupled to a supply voltage (e.g., supply voltage VDD).

In some embodiments, the method 1000 further comprises the following step: forming the gate isolation 151 between the metal gate structures 110 and 210 to electrically separate the metal gate structure 110 from the metal gate structure 210.

In some embodiments, the method 1000 further comprises the following step: forming the interconnect structure 141 extending along the direction Z to couple the active region 321 to the metal gate structure 210.

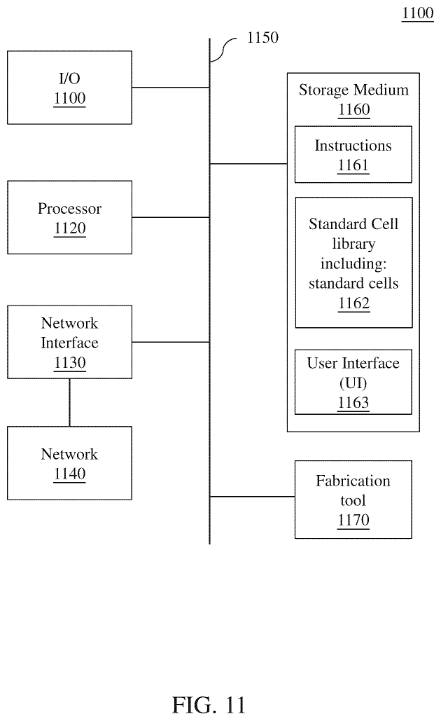

Reference is now made to FIG. 11. FIG. 11 is a block diagram of an electronic design automation (EDA) system 1100 for designing the integrated circuit layout design, in accordance with some embodiments of the present disclosure. The EDA system 1100 is configured to implement one or more steps of the method 1000 disclosed in FIG. 10, and circuit and layout design disclosed in FIGS. 1-3, 4A-4B, 5-6, 7A-7C, 8 and 9A-9B.

In some embodiments, the EDA system 1100 is a general purpose computing device including a hardware processor 1120 and a non-transitory, computer-readable storage medium 1160. The storage medium 1160, amongst other things, is encoded with, i.e., stores, instructions (computer program code) 1161, i.e., a set of executable instructions. Execution of the instructions 1161 by hardware processor 1120 represents (at least in part) an EDA tool which implements a portion or all of, e.g., the method 1000, and method for implementing circuit and layout design disclosed in FIGS. 1-3, 4A-4B, 5-6, 7A-7C, 8 and 9A-9B.

The processor 1120 is electrically coupled to the storage medium 1160 via a bus 1150. The processor 1120 is also electrically coupled to an input/output (I/O) interface 1110 and a fabrication tool 1170 by bus 1150. A network interface 1130 is also electrically connected to processor 1120 via bus 1150. Network interface 1130 is connected to a network 1140, so that processor 1120 and the storage medium 1160 are capable of connecting to external elements via the network 1140. The processor 1120 is configured to execute the instructions 1161 encoded in the storage medium 1160 in order to cause the EDA system 1100 to be usable for performing a portion or all of the noted processes and/or methods. In one or more embodiments, the processor 1120 is a central processing unit (CPU), a multi-processor, a distributed processing system, an application specific integrated circuit (ASIC), and/or a suitable processing unit.

In one or more embodiments, the storage medium 1160 is an electronic, magnetic, optical, electromagnetic, infrared, and/or a semiconductor system (or apparatus or device). For example, the storage medium 1160 includes a semiconductor or solid-state memory, a magnetic tape, a removable computer diskette, a random access memory (RAM), a read-only memory (ROM), a rigid magnetic disk, and/or an optical disk. In one or more embodiments using optical disks, the storage medium 1160 includes a compact disk-read only memory (CD-ROM), a compact disk-read/write (CD-R/W), and/or a digital video disc (DVD).

In one or more embodiments, the storage medium 1160 stores the instructions 1161 configured to cause the EDA system 1100 (where such execution represents (at least in part) the EDA tool) to be usable for performing a portion or all of the noted processes and/or methods. In one or more embodiments, the storage medium 1160 also stores information which facilitates performing a portion or all of the noted processes and/or methods. In one or more embodiments, storage medium 1160 stores library 1162 of standard cells including such standard cells as disclosed herein, for example, circuits disclosed in FIGS. 1-3, 4A-4B, 5-6, 7A-7C, 8 and 9A-9B.

The EDA system 1100 includes the I/O interface 1110. The I/O interface 1110 is coupled to external circuitry. In one or more embodiments, the I/O interface 1110 includes a keyboard, keypad, mouse, trackball, trackpad, touchscreen, and/or cursor direction keys for communicating information and commands to the processor 1120.

EDA system 1100 also includes the network interface 1130 coupled to processor 1120. The network interface 1130 allows the EDA system 1100 to communicate with the network 1140, to which one or more other computer systems are connected. The network interface 1130 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more EDA systems 1100.

The EDA system 1100 also includes the fabrication tool 1170 coupled to the processor 1120. The fabrication tool 1170 is configured to fabricate integrated circuits, e.g., the circuits in FIGS. 1-3, 4A-4B, 5-6, 7A-7C, 8 and 9A-9B., according to the design files processed by the processor 1120.

The EDA system 1100 is configured to receive information through I/O interface 1110. The information received through the I/O interface 1110 includes one or more of instructions, data, design rules, libraries of standard cells, and/or other parameters for processing by the processor 1120. The information is transferred to the processor 1120 via the bus 1150. The EDA system 1100 is configured to receive information related to a user interface (UI) through the I/O interface 1110. The information is stored in computer-readable storage medium 1160 as user interface (UI) 1163.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by the EDA system 1100. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, for example, one or more of an optical disk, such as a DVD, a magnetic disk, such as a hard disk, a semiconductor memory, such as a ROM, a RAM, a memory card, and the like.

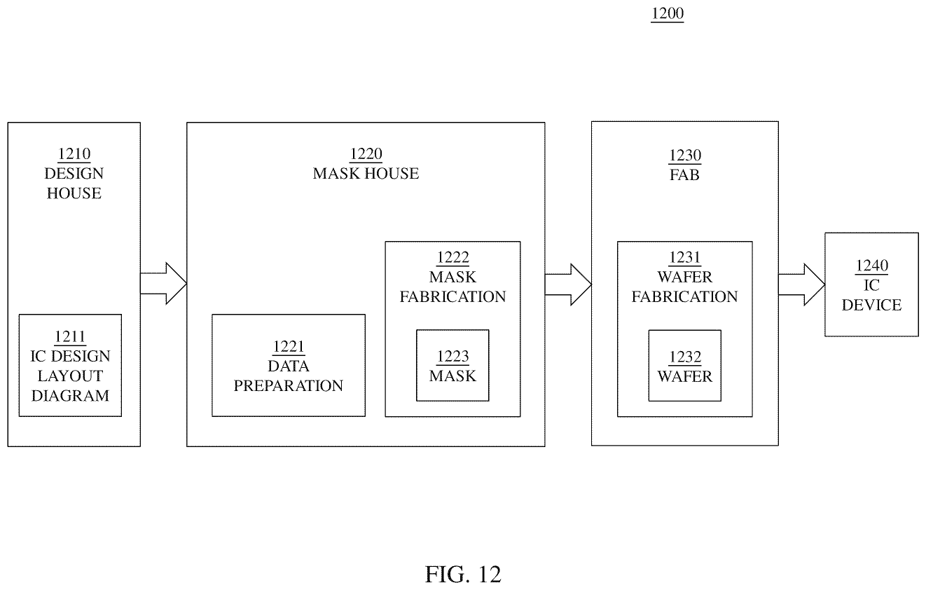

FIG. 12 is a block diagram of IC manufacturing system 1200, and an IC manufacturing flow associated therewith, in accordance with some embodiments. In some embodiments, based on a layout diagram, at least one of (A) one or more semiconductor masks or (B) at least one component in a layer of a semiconductor integrated circuit is fabricated using the IC manufacturing system 1200.

In FIG. 12, the IC manufacturing system 1200 includes entities, such as a design house 1210, a mask house 1220, and an IC manufacturer/fabricator (“fab”) 1230, that interact with one another in the design, development, and manufacturing cycles and/or services related to manufacturing an IC device 1240. The entities in IC manufacturing system 1200 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1210, mask house 1220, and IC fab 1230 is owned by a single larger company. In some embodiments, two or more of design house 1210, mask house 1220, and IC fab 1230 coexist in a common facility and use common resources.

Design house (or design team) 1210 generates an IC design layout diagram 1211. The IC design layout diagram 1211 includes various geometrical patterns, for example, an IC layout design corresponding to circuit and layout design disclosed in FIGS. 1-3, 4A-4B, 5-6, 7A-7C, 8 and 9A-9B. The geometrical patterns correspond to patterns of metal, oxide, or semiconductor layers that make up the various components of IC device 1240 to be fabricated. The various layers combine to form various IC features. For example, a portion of IC design layout diagram 1211 includes various IC features, such as an active region, gate electrode, source and drain, conductive segments or vias of an interlayer interconnection, to be formed in a semiconductor substrate (such as a silicon wafer) and various material layers disposed on the semiconductor substrate. Design house 1210 implements a proper design procedure to form IC design layout diagram 1211. The design procedure includes one or more of logic design, physical design or place and route. The IC design layout diagram 1211 is presented in one or more data files having information of the geometrical patterns. For example, the IC design layout diagram 1211 can be expressed in a GDSII file format or DFII file format.

The mask house 1220 includes data preparation 1221 and mask fabrication 1222. The mask house 1220 uses the IC design layout diagram 1211 to manufacture one or more masks 1223 to be used for fabricating the various layers of IC device 1240 according to the IC design layout diagram 1211. The mask house 1220 performs mask data preparation 1221, where IC design layout diagram 1211 is translated into a representative data file (“RDF”). The mask data preparation 1221 provides the RDF to the mask fabrication 1222. The mask fabrication 1222 includes a mask writer. A mask writer converts the RDF to an image on a substrate, such as a mask (reticle) 1223 or a semiconductor wafer 1232. The IC design layout diagram 1211 is manipulated by the mask data preparation 1221 to comply with particular characteristics of the mask writer and/or requirements of the IC fab 1230. In FIG. 12, the data preparation 1221 and the mask fabrication 1222 are illustrated as separate elements. In some embodiments, the data preparation 1221 and the mask fabrication 1222 can be collectively referred to as mask data preparation.

In some embodiments, the data preparation 1221 includes optical proximity correction (OPC) which uses lithography enhancement techniques to compensate for image errors, such as those that can arise from diffraction, interference, other process effects and the like. The OPC adjusts the IC design layout diagram 1211. In some embodiments, the data preparation 1221 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats the OPC as an inverse imaging problem.

In some embodiments, data preparation 1221 includes a mask rule checker (MRC) that checks the IC design layout diagram 1211 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 1211 to compensate for limitations during the mask fabrication 1222, which may undo part of the modifications performed by OPC in order to meet mask creation rules.

In some embodiments, data preparation 1221 includes lithography process checking (LPC) that simulates processing that will be implemented by the IC fab 1230 to fabricate the IC device 1240. The LPC simulates this processing based on IC design layout diagram 1211 to create a simulated manufactured device, such as IC device 1240. The processing parameters in LPC simulation can include parameters associated with various processes of the IC manufacturing cycle, parameters associated with tools used for manufacturing the IC, and/or other aspects of the manufacturing process. The LPC takes into account various factors, such as aerial image contrast, depth of focus (“DOF”), mask error enhancement factor (“MEEF”), other suitable factors, and the like or combinations thereof. In some embodiments, after a simulated manufactured device has been created by the LPC, if the simulated device is not close enough in shape to satisfy design rules, the OPC and/or the MRC are be repeated to further refine the IC design layout diagram 1211.

It should be understood that the above description of data preparation 1221 has been simplified for the purposes of clarity. In some embodiments, data preparation 1221 includes additional features such as a logic operation (LOP) to modify the IC design layout diagram 1211 according to manufacturing rules. Additionally, the processes applied to IC design layout diagram 1211 during data preparation 1221 may be executed in a variety of different orders.

After the data preparation 1221 and during mask fabrication 1222, a mask 1223 or a group of masks 1223 are fabricated based on the modified IC design layout diagram 1211. In some embodiments, the mask fabrication 1222 includes performing one or more lithographic exposures based on the IC design layout diagram 1211. In some embodiments, an electron-beam (e-beam) or a mechanism of multiple e-beams is used to form a pattern on a mask (photomask or reticle) 1223 based on the modified IC design layout diagram 1211. The mask 1223 can be formed in various technologies. In some embodiments, the mask 1223 is formed using binary technology. In some embodiments, a mask pattern includes opaque regions and transparent regions. A radiation beam, such as an ultraviolet (UV) beam, used to expose the image sensitive material layer (for example, photoresist) which has been coated on a wafer, is blocked by the opaque region and transmits through the transparent regions. In one example, a binary mask version of the mask 1223 includes a transparent substrate (for example, fused quartz) and an opaque material (for example, chromium) coated in the opaque regions of the binary mask. In another example, the mask 1223 is formed using a phase shift technology. In a phase shift mask (PSM) version of the mask 1223, various features in the pattern formed on the phase shift mask are configured to have proper phase difference to enhance the resolution and imaging quality. In various examples, the phase shift mask can be attenuated PSM or alternating PSM. The mask(s) generated by the mask fabrication 1222 is used in a variety of processes. For example, such a mask(s) is used in an ion implantation process to form various doped regions in the semiconductor wafer 1232, in an etching process to form various etching regions in the semiconductor wafer 1232, and/or in other suitable processes.

The IC fab 1230 includes wafer fabrication 1231. The IC fab 1230 is an IC fabrication business that includes one or more manufacturing facilities for the fabrication of a variety of different IC products. In some embodiments, the IC Fab 1230 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

The IC fab 1230 uses mask(s) 1223 fabricated by mask house 1220 to fabricate the IC device 1240. Thus, the IC fab 1230 at least indirectly uses IC design layout diagram 1211 to fabricate the IC device 1240. In some embodiments, the semiconductor wafer 1233 is fabricated by the IC fab 1230 using the mask(s) 1223 to form IC device 1240. In some embodiments, the IC fabrication includes performing one or more lithographic exposures based at least indirectly on the IC design layout diagram 1211. Semiconductor wafer 1233 includes a silicon substrate or other proper substrate having material layers formed thereon. The semiconductor wafer 1233 further includes one or more of various doped regions, dielectric features, multilevel interconnects, and the like (formed at subsequent manufacturing steps).

As described above, the semiconductor device and method of manufacturing the semiconductor device are provided. The semiconductor device has a CFET structure that providing decoupling capacitors to a circuit. The CFET structure design helps reduce area usage compared to some approaches. In addition, metal routing in the front side and backside of the CFET structure help improve design flexibility.

In some embodiments, a semiconductor device is provided. The semiconductor device comprises a first circuit and a capacitor circuit. The first circuit has an input terminal configured to receive an input signal. The capacitor circuit comprises a first transistor and a second transistor. The first transistor is coupled between a first supply voltage and the input terminal. Source/drain terminals of the first transistor are coupled to each other. The second transistor is stacked above the first transistor and coupled between a second supply voltage and the input terminal. Source/drain terminals of the second transistor are coupled to each other. The first and second transistors are decoupling capacitors of the first circuit.

In some embodiments, a semiconductor device is provided. The semiconductor device comprises a first circuit and a complementary field-effect transistor structure. The first circuit has an input terminal configured to receive an input signal. The complementary field-effect transistor structure comprises first and second transistors. The first transistor is coupled to the input terminal. The second transistor is above the first transistor and coupled to the first transistor and the input terminal. The first and second transistors are decoupling capacitors to the input terminal.

In some embodiments, a method for forming a semiconductor device is provided. The method comprises: forming a first active region extending along a first direction on a substrate; forming a second active region extending along the first direction above the first active region; forming a first gate structure extending along a second direction across the first active region, wherein the first active region and the first gate structure correspond to a first transistor; forming a second gate structure extending along the second direction above the first gate structure, wherein the second active region and the second gate structure correspond to a second transistor; forming a first metal line in a front side of the semiconductor device to couple the first and second transistors to an input terminal of a first circuit, wherein the first and second transistors are decoupling capacitors of the first circuit; and thinning the substrate and forming a second metal line in a backside of the semiconductor device, wherein the second metal line is coupled to a first supply voltage.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first circuit having an input terminal configured to receive an input signal; and
a capacitor circuit comprising:
a first transistor coupled between a first supply voltage and the input terminal, wherein source/drain terminals of the first transistor are coupled to each other; and
a second transistor stacked above the first transistor and coupled between a second supply voltage and the input terminal, wherein source/drain terminals of the second transistor are coupled to each other,
wherein the first and second transistors are decoupling capacitors of the first circuit.

2. The semiconductor device of claim 1, wherein a gate terminal of the first transistor extends vertically to contact a gate terminal of the second transistor,
wherein the gate terminal of the first transistor overlaps the gate terminal of the second transistor.

3. The semiconductor device of claim 1, wherein the first supply voltage is higher than the second supply voltage.

4. The semiconductor device of claim 3, wherein a voltage range of the input signal is from the first supply voltage to the second supply voltage.

5. The semiconductor device of claim 3, wherein the first transistor is p-type, the source/drain terminals of the first transistor are coupled to the first supply voltage and a gate terminal of the first transistor is coupled to the input terminal.

6. The semiconductor device of claim 5, wherein the second transistor is n-type, the source/drain terminals of the second transistor are coupled to the second supply voltage and a gate terminal of the second transistor is coupled to the input terminal.

7. The semiconductor device of claim 1, wherein the first transistor is coupled to the first supply voltage through a first metal line in a backside of the semiconductor device,
wherein the second transistor is coupled to the second supply voltage through a second metal line in a front side of the semiconductor device.

8. A semiconductor device, comprising:
a first circuit having an input terminal configured to receive an input signal; and
a complementary field-effect transistor structure comprising:
a first transistor coupled to the input terminal; and
a second transistor above the first transistor and coupled to the first transistor and the input terminal, wherein the first and second transistors are decoupling capacitors to the input terminal.

9. The semiconductor device of claim 8, wherein the first transistor is p-type, source/drain terminals of the first transistor are coupled to a first supply voltage and a gate terminal of the first transistor is coupled to the input terminal.

10. The semiconductor device of claim 9, wherein the second transistor is n-type, source/drain terminals of the second transistor are coupled to a second supply voltage and a gate terminal of the second transistor is coupled to the input terminal.

11. The semiconductor device of claim 10, wherein a voltage level of the input signal ranges from the first supply voltage to the second supply voltage.

12. The semiconductor device of claim 9, wherein the second transistor is p-type, source/drain terminals of the second transistor are coupled to the input terminal and a gate terminal of the second transistor is coupled to a second supply voltage.

13. The semiconductor device of claim 8, wherein the first transistor is n-type, source/drain terminals of the first transistor are coupled to the input terminal and a gate terminal of the first transistor is coupled to a first supply voltage,
wherein the second transistor is n-type, source/drain terminals of the second transistor are coupled to a second supply voltage and a gate terminal of the second transistor is coupled to the input terminal.

14. The semiconductor device of claim 8, wherein the gate terminals of the first and second transistors are coupled to the input terminal,
wherein source/drain terminals of the first transistor and source/drain terminals of the second transistor are coupled to a first supply voltage.

15. The semiconductor device of claim 8, further comprising:
a first gate structure extending along a first direction;
a first active region extending along a second direction through the first gate structure, wherein the first gate structure and the first active region correspond to the first transistor;
a second gate structure above the first gate structure; and
a second active region extending along the second direction through the second gate structure, wherein the second gate structure and the second active region overlap the first gate structure and the first active region respectively in a layout view.

16. The semiconductor device of claim 15, further comprising:
first and second source/drain contacts disposed above the second active region;
a metal line in a backside of the semiconductor device below the first active region, wherein the metal line is coupled to the input terminal; and
an interconnect structure extending vertically to connect the first and second source/drain contacts to the metal line,
wherein the first gate structure is coupled to the metal line.

17. The semiconductor device of claim 15, further comprising:
first and second source/drain contacts disposed above the second active region;
a first metal line coupled to the first and second source/drain contacts in a front side of the semiconductor device, wherein the first metal line is configured to transmit a first supply voltage;
third and fourth source/drain contacts disposed below the first active region; and
a second metal line coupled to the third and fourth source/drain contacts in a backside of the semiconductor device, wherein the second metal line is configured to transmit a second supply voltage.

18. A method for forming a semiconductor device, comprising:
forming a first active region extending along a first direction on a substrate;
forming a second active region extending along the first direction above the first active region;
forming a first gate structure extending along a second direction across the first active region, wherein the first active region and the first gate structure correspond to a first transistor;
forming a second gate structure extending along the second direction above the first gate structure, wherein the second active region and the second gate structure correspond to a second transistor;
forming a first metal line in a front side of the semiconductor device to couple the first and second transistors to an input terminal of a first circuit,
wherein the first and second transistors are decoupling capacitors of the first circuit; and
thinning the substrate and forming a second metal line in a backside of the semiconductor device, wherein the second metal line is coupled to a first supply voltage.

19. The method of claim 18, further comprising:
forming a gate isolation between the first and second gate structures to electrically separate the first gate structure from the second gate structure.

20. The method of claim 18, further comprising:
forming an interconnect structure extending along a third direction to couple the second active region to the first gate structure.
